(19) United States
(12) Patent Application Publication
(10) Pub. No.: US 2011/0244665 A1
(43) Pub. Date: Oct. 6, 2011

(54) MANUFACTURING METHOD OF GaN BASED SEMICONDUCTOR EPITAXIAL SUBSTRATE

(76) Inventors: Makoto MIKAMI, Toda-shi (JP); Misao Takakusaki, Toda-shi (JP); Taku Yoshida, Toda-shi (JP); Satoru Morioka, Toda-shi (JP)

(21) Appl. No.: 13/075,659

(22) Filed: Mar. 30, 2011

(30) Foreign Application Priority Data
Mar. 31, 2010 (JP) 2010-081045

(51) Int. Cl. H01L 21/20

(52) U.S. Cl. 438/478; 257/E21.09

(57) ABSTRACT

A low-temperature protective layer having AlN is grown on a rare earth perovskite substrate and a first GaN based semiconductor layer having Alₓ₁Ga₁₋ₓ₁N where composition x1 of Al is 0.40≦x1≦0.45 is grown thereon. Then, a second GaN semiconductor layer having Alₓ₂Ga₁₋ₓ₂N where composition x2 of Al is 0≦x2≦0.45 is grown on the first GaN based semiconductor layer.

### BACKGROUND OF THE INVENTION

1. Field of the Invention

The present invention relates to a manufacturing method of a GaN based semiconductor epitaxial substrate including gallium nitride (GaN) or AlₓGa₁₋ₓN (0<x≦1) mixed crystal which is epitaxially grown on a substrate and especially to a method of growing a GaN based semiconductor film having a high crystallinity by way of Hydride Vapor Phase Epitaxy (HVPE) method.

2. Description of the Related Arts

Recently, a semiconductor material including a nitride compound semiconductor such as aluminum nitride (AlN), gallium nitride (GaN), or a mixed crystal thereof (AlₓGa₁₋ₓN (0<x<1)) is attracting attention as a light emitting material having blue or purple ultraviolet, or ultraviolet having a shorter wavelength. Hereinafter, these materials will be referred to as a GaN based semiconductor.

Conventionally, it has been difficult to grow such a GaN based semiconductor material into a large-sized single crystalline ingot and therefore a vapor phase epitaxial method such as the HVPE method has been used to allow epitaxial growth of the material on a substrate made of a different material. At this time, sapphire is mainly used as a substrate for growth.

In a case where sapphire is used as a substrate for growth, because lattice mismatch ratio between sapphire and GaN or AlN exceeds 20%, it is difficult to allow epitaxial growth of a good GaN thick film or the like. Therefore, a method of including a complex procedure such as causing the growth after a special mask or the like is previously formed on the substrate for growth has been proposed (e.g., non-patent documents 1 to 3).

In the non-patent document 1 (Japanese Journal of Applied Physics 36 (1997) L889-L902), Usui et al. grew a GaN thick film on sapphire by the HVPE method. Specifically, a {1-101} facet is formed on a sapphire substrate by a silicon oxide (SiO₂) mask and a GaN thick film is grown thereon to realize dislocation density of less than 6×10⁷/cm².

In the non-patent document 2 (Japanese Journal of Applied Physics 40 (2001) L1280-L1282), Kinoshita et al. report that zirconium boride (ZrB₂) has the same crystal structure as AlN and GaN and lattice constant close to AlN and GaN (lattice mismatch ratio between ZrB₂ and AlN is 1.9% and lattice mismatch ratio between ZrB₂ and GaN is 0.5%) and therefore ZrB₂ is suitable as a substrate for growth of a GaN thick film.

In the non-patent document 3 (Japanese Journal of Applied Physics 39 (2000) L2399-L2401), Wakahara et al. grew GaN on an NdGaO₃ (hereinafter referred to as NGO) substrate by way of the HVPE method. Although the NGO and GaN respectively has different crystalline structure, as shown in FIG. 6, an atomic arrangement of a {0001} surface of GaN overlaps an atomic arrangement of a {101} surface or a {011} surface of NGO and lattice mismatch ratio is 1.70 or less. Such a matching of atomic arrangements is called pseudo-lattice matching. Due to this pseudo-lattice matching, it becomes possible to grow a GaN thick film having a good crystallinity and to realize dislocation density of less than 10⁶/cm².

However, according to the method described in the non-patent document 1, there are problems such as, depending on the case, there appears an area of high dislocation density in a part of the GaN thick film thus obtained and there exists an unusable part. Moreover, because of a difference in coefficients of thermal expansion between sapphire and GaN, a GaN based semiconductor epitaxial wafer after growth is warped due to thermal stress caused by high growth temperature at a time of the crystal growth.

According to the method described in the non-patent document 2, there is a problem that a large amount of boron (B) of the ZrB₂ substrate enters the GaN film when the crystal grows and characteristics as a semiconductor is significantly deteriorated.

According to the method described in the non-patent document 3, it becomes possible to grow a GaN film having a better crystallinity compared to a case where sapphire is used as the substrate for growth. However, lattice mismatch ratio is not zero and therefore appearance of dislocation is inevitable. Moreover, due to a difference between coefficients of thermal expansion of NGO and GaN, similarly to the case where sapphire is used as the substrate for growth, the GaN based semiconductor epitaxial substrate after growth is warped.

Because of the above-mentioned problems with the conventional methods, it becomes difficult to effectively deal with a case where a GaN thick film having superior crystallinity (e.g., dislocation density of 10⁵/cm² or less) and smaller amount of warping is required.

### SUMMARY OF THE INVENTION

The present invention has been made to solve at least one of the above-mentioned problems and is directed to provide a manufacturing method of a GaN based semiconductor epitaxial substrate which enables epitaxial growth of a GaN based substrate having a superior crystallinity without warping.

According to an aspect of the present invention, there is provided a manufacturing method of a GaN based semiconductor epitaxial substrate including:

a first step of growing a low-temperature protective layer having AlN on a rare earth perovskite substrate;

a second step of growing a first GaN based semiconductor layer having Alₓ₁Ga₁₋ₓ₁N, in which composition x1 of Al is 0.40≦x1≦0.45, on the low-temperature protective layer; and

a third step of growing a second GaN semiconductor layer having Alₓ₂Ga₁₋ₓ₂N, in which composition x2 of Al is 0≦x2≦0.45, on the first GaN based semiconductor layer.

It is preferable that the above-mentioned manufacturing method of a GaN based semiconductor epitaxial substrate further includes a fourth step of growing a composition gradient layer having Alₓ₃Ga₁₋ₓ₃N, in which the composition x3 of Al gradually becomes smaller from the composition x1, on the first GaN based semiconductor layer, wherein

the second GaN based semiconductor layer is grown on the composition gradient layer in the third step.

It is preferable in the above-mentioned manufacturing method of the GaN based semiconductor epitaxial substrate that the first and the second GaN based semiconductor layers are epitaxially grown on the rare earth perovskite substrate by use of HVPE method supplying chloride gas of one or a plurality of III group elements including Ga and NH₃ and to cause them react.

According to the present invention, it becomes possible to realize epitaxial growth of a GaN based semiconductor (GaN thick film) having a superior crystallinity without warping. Therefore, it becomes possible to improve device characteristics if a semiconductor device is manufactured by use of the GaN based semiconductor epitaxial substrate itself or an independent substrate obtained by the GaN based semiconductor epitaxial substrate.

### BRIEF DESCRIPTION OF THE DRAWINGS

The above and other objects, advantages and features of the present invention will become more fully understood from the detailed description given hereinbelow and the appended drawings which are given by way of illustration only, and thus are not intended as a definition of the limits of the present invention, and wherein:

FIG. 1 is a view showing temperature dependence of lattice constants of GaN, AlN, and NGO;

FIGS. 2A and 2B are views showing thermal stress that AlN or Al_{0.4}Ga_{0.6}N grown on the NGO substrate receives;

FIG. 3 is a view showing laminated structure of a GaN epitaxial substrate according to an embodiment of the present invention;

FIG. 4 is a view showing laminated structure of a GaN epitaxial substrate according to a comparison example 1;

FIG. 5 is a view showing laminated structure of a GaN epitaxial substrate according to a comparison example 2; and

FIG. 6 is a view showing a lattice arrangement of GaN on NGO.

### DESCRIPTION OF THE PREFERRED EMBODIMENTS

Hereinafter, an embodiment of the present invention will be explained in detail on the basis of the drawings.

In the present embodiment, an explanation will be given of a case where GaN which is a GaN based semiconductor is epitaxially grown on an NGO substrate including a rare earth perovskite by way of the Hydride Vapor Phase Epitaxy (HVPE) method to manufacture a GaN epitaxial substrate.

At this time, a low temperature protective layer including AlN is grown on the NGO substrate, a first GaN based semiconductor layer having Alₓ₁Ga₁₋ₓ₁N is grown on the low temperature protective layer, where composition x1 of Al is 0.40≦x1≦0.45 which highly lattice matches with the NGO, and subsequently a composition gradient layer having Alₓ₃Ga₁₋ₓ₃N is grown, where the composition x3 of Al gradually becomes smaller from the composition x1. Then, a second GaN semiconductor layer of Alₓ₂Ga₁₋ₓ₂N having an aimed composition (composition x2 of Al is 0≦x2≦0.45) is grown on the composition gradient layer.

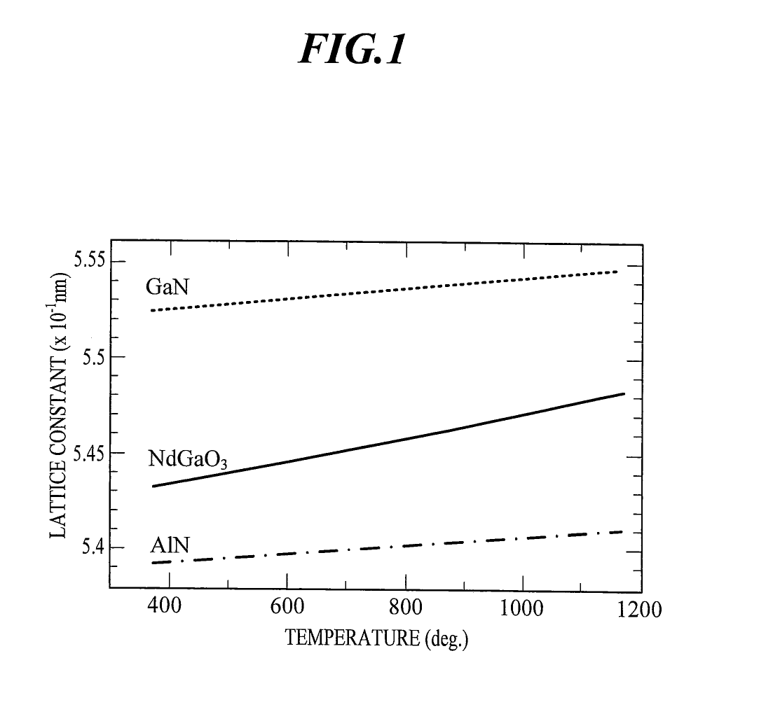

FIG. 1 is a view showing temperature dependence of lattice constant of GaN, AlN, and NGO. Moreover, degree of mismatching when atomic arrangement of AlN and Al_{0.4}Ga_{0.6}N are matched on the NGO substrate in growth temperature of GaN and room temperature (difference between lattice constants in room temperature Δa1, difference between lattice constants in growth temperature Δa2) and difference between them (Δa1−Δa2) calculated on the basis of change in temperature of lattice constants of each crystal shown in FIG. 1 are shown in Table. 1.

TABLE 1

| | AlN | Al_{0.4}Ga_{0.6}N |
|---|---|---|
| Lattice constant difference between | −0.040 | 0.040 |
| NGO in room temperature Δa₁ (nm) | | |
| Lattice constant difference between | −0.078 | 0.001 |
| NGO in growth temperature Δa₂ (nm) | | |
| Δa₂ (nm) − Δa₁ (nm) | −0.038 | 0.039 |

The thermal stress that the AlN layer and the Al_{0.4}Ga_{0.6}N receives when the layers are grown in the growth temperature of GaN and cooled down to the room temperature is proportional to difference between the value of degree of lattice mismatching in the growth temperature and in the room temperature (in Table 1, −0.038 for AlN, 0.039 for Al_{0.4}Ga_{0.5}N). Therefore, in the case of AlN and Al_{0.4}Ga_{0.6}N, the layers receive thermal stress of approximately similar amount in opposite directions, respectively.

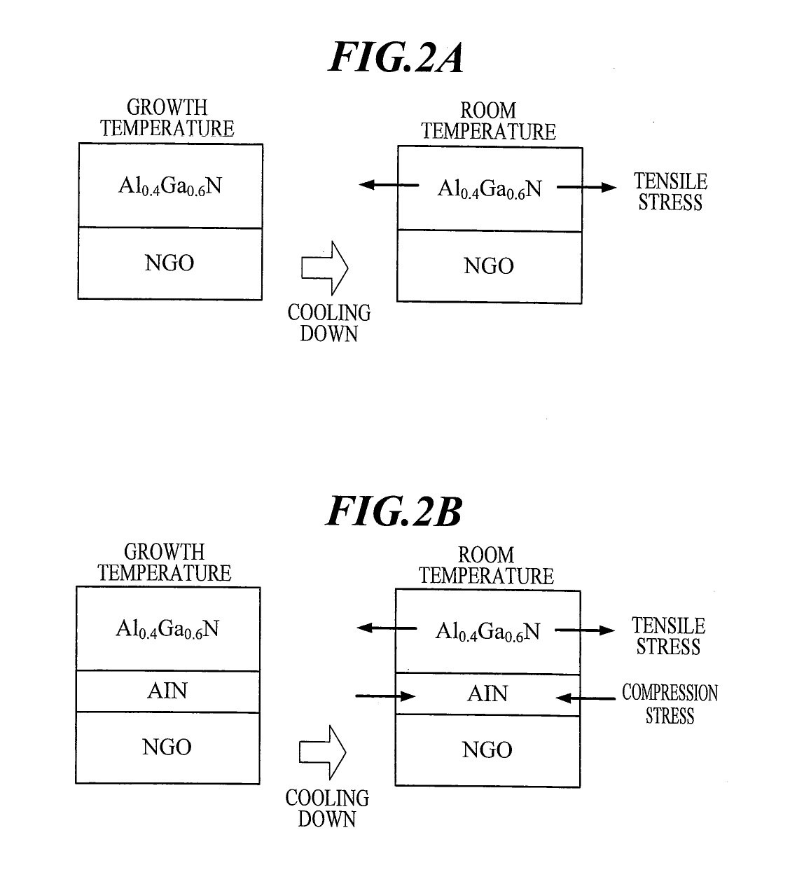

That is, as shown in FIG. 2A, if the Al_{0.4}Ga_{0.6}N layer is directly grown on the NGO substrate, while lattice mismatching in the growth temperature is small (0.001 in Table 1), lattice mismatching becomes large in the room temperature (0.040 in Table 1). Therefore, the layer receives tensile stress equivalent to the difference (Δa₂−Δa₁=0.039) when cooled.

Therefore, if the AlN layer is sandwiched between the NGO substrate and the Al_{0.4}Ga_{0.6}N layer as shown in FIG. 2B, the AlN layer receives compression stress and the Al_{0.4}Ga_{0.6}N layer receives the tensile stress. Therefore, the two stresses are balanced out. Then, if a GaN thick film is formed on the Al_{0.4}Ga_{0.6}N layer, a GaN epitaxial substrate having the GaN thick film with less warping is manufactured. Especially, according to the keen study by the inventors, in a case where a composite layer of Al_{0.42}Ga_{0.58}N (a first GaN based semiconductor layer) was grown on the AlN layer, a GaN thick film layer (a second GaN based semiconductor layer) showed the best characteristics.

### Embodiment

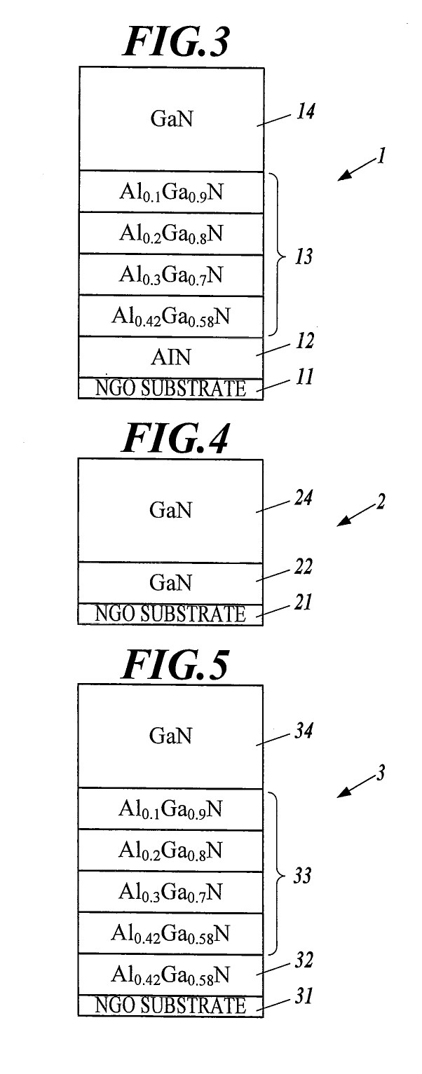

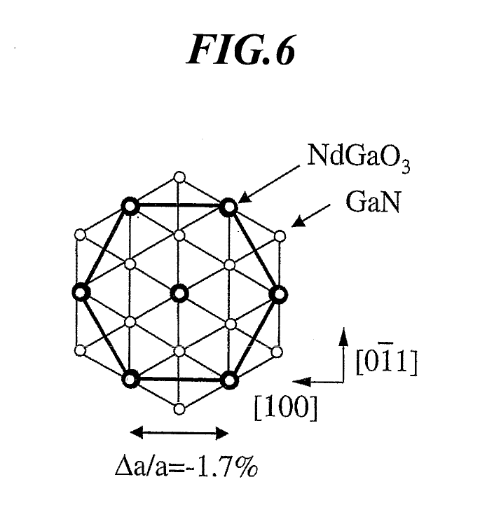

In the embodiment, a GaN epitaxial substrate 1 having a laminated layer structure shown in FIG. 3 is manufactured. As shown in FIG. 3, the GaN epitaxial substrate 1 according to the embodiment includes an AlN low temperature protective layer 12, an AlGaN composition gradient layer 13, and a GaN thick film which are sequentially formed on an NGO substrate 11.

First, an NGO (011) surface having a thickness of 450 nm and diameter of 50 mm is prepared as a substrate for growth (NGO substrate) 11, and the NGO substrate 11, Ga raw material, and Al raw material are provided in an HVPE device. Then, temperature of the Ga raw material part and Al raw material part are increased to 850° C. and 800° C., respectively.

Here, flow rate of N₂ carrier gas is set to 12 L/min and flow rate in an HCl line to the Ga raw material part, in an HCl line to the Al raw material part, and in an NH₃ line are respectively set to be 1.4 L/min, 1.4 L/min, and 1.64 L/min after attenuation by the N₂ carrier gas.

Next, the growth temperature (temperature of the NGO substrate) is fixed at 600° C., a chloride gas (AlCl) generated by the Al and HCl is supplied through an Al raw material line, and NH₃ is supplied through the NH₃ line. Then, the low temperature protective layer 12 including AlN is grown to about 100 nm on the NGO substrate. Subsequently, supply of the raw material gas is stopped and the growth temperature is increased up to 980° C.

Next, the AlCl is supplied through the Al raw material line, NH₃ is supplied through the NH₃ line, and at the same time a chloride gas generated by Ga and HCl (GaCl) is supplied through a Ga raw material line. At this time, flow rate is adjusted so that composition x of Al becomes 0.42, 0.3, 0.2, and 0.1. Then, the composition gradient layers 13 having AlₓGa₁₋ₓN (x=0.42, 0.3, 0.2, and 0.1) are grown to respectively have a thickness of approximately 100 μm on the AlN low temperature protective layer 12. Here, the lowest layer of the composition gradient layers 13 (Al composition x=0.42) becomes the first GaN based semiconductor layer in the present invention.

Next, supply of the raw material gas through the Al raw material line is stopped, GaCl is supplied through the Ga raw material line, and NH₃ is supplied through the NH₃ line. Then, an AlₓGa₁₋ₓN film where x=0.0, that is, a GaN thick film (a second GaN based semiconductor layer) 14 is grown to 1600 μm on the AlₓGa₁₋ₓN composition gradient layer 13.

Subsequently, the temperature is cooled down to the room temperature. In this cooling process, the GaN thick film 14 receives tensile stress from the NGO substrate 11. However, the film receives compression stress from the AlN low temperature protective layer and the stresses are balanced out and influence by the thermal stress is reduced.

A surface of the GaN thick film thus obtained is analyzed by an X-ray diffractometer and a diffraction pattern corresponding to a (0002) surface and a (0004) surface of GaN is observed.

Moreover, after the GaN thick film 14 is polished for measurement of cathodoluminescence, not a single dark spot which appears due to existence of threading dislocation can be observed within an observation surface of 250 μm×250 μm. Thus, it is calculated that the dislocation density of the threading dislocation is 1.6×10³/cm².

Further, a total of five spots including one in center of the surface of the GaN thick film and four spots located in the edge portions on an orthogonal axis passing through the center point are set to be measurement points to measure an off angle to a [0001] direction. Then, off angle distribution regarding the off angles in the five measurement points are calculated by (maximum value-minimum value)/2. The off angle distribution is ±0.1° or less.

Thus, according to the present embodiment, a GaN thick film having good crystallinity without warping (with small off angle distribution) is realized.

### Comparison Example 1

In the comparison example 1, a GaN epitaxial substrate 2 having a laminated structure shown in FIG. 4 is manufactured. As shown in FIG. 4, the GaN epitaxial substrate 2 according to the comparison example 1 has an NGO substrate 21 on which a GaN low temperature protective layer 22 and a GaN thick film 24 are sequentially formed. That is, compared to the GaN epitaxial substrate 1 according to the embodiment, the differences are that the low temperature protective layer 22 includes GaN and the composition gradient layer 13 is not formed.

First, an NGO (011) surface having a thickness of 450 nm and diameter of 50 mm is prepared as a substrate for growth 21 and the NGO substrate 21 and Ga raw material are provided in an HVPE device. Then, temperature of the Ga raw material is increased to 850° C.

Here, flow rate of N₂ carrier gas is set to 12 L/min and flow rate in an HCl line to the Ga raw material part, and in an NH₃ line are respectively set to be 1.4 L/min and 1.64 L/min after attenuation by the N₂ carrier gas.

Next, the growth temperature (temperature of the NGO substrate) is fixed at 600° C., GaCl is supplied through a Ga raw material line, and NH₃ is supplied through the NH₃ line. Then, the low temperature protective layer 22 including GaN is grown to approximately 100 nm on the NGO substrate 21. Subsequently, supply of the raw material gas is stopped and the growth temperature is increased up to 980° C.

Next, GaCl is supplied again through the Ga raw material line and NH₃ is supplied through the NH₃ line to grow the GaN thick film 24 to 2000 μm on the GaN low temperature protective layer 22. Subsequently, the temperature is cooled down to the room temperature. In this cooling process, the GaN thick film 24 receives tensile stress from the NGO substrate 21.

A surface of the GaN thick film thus obtained is analyzed by an X-ray diffractometer to observe a diffraction pattern corresponding to a (0002) surface and a (0004) surface of GaN. Moreover, after the GaN thick film 24 is polished for measurement of cathodoluminescence, threading dislocation of approximately between 10⁵ and 10⁸/cm² is observed. Further, when off angle is measured similarly to the embodiment, off angle distribution is approximately ±0.4°.

Thus, the GaN epitaxial substrate 2 obtained by the comparison example 1 has lower crystallinity and larger warping when compared to the GaN epitaxial substrate obtained by the embodiment.

### Comparison Example 2

In the comparison example 2, a GaN epitaxial substrate 3 having a laminated structure shown in FIG. 5 is manufactured. As shown in FIG. 5, the GaN epitaxial substrate 3 according to the comparison example 2 has an NGO substrate 31 on which an AlGaN low temperature protective layer 32, an AlGaN composition gradient layer 33, and a GaN thick film 34 are sequentially formed. That is, compared to the GaN epitaxial substrate 1 according to the embodiment, there is a difference in the configuration of the low temperature protective layer 32.

First, an NGO (011) surface having a thickness of 450 nm and diameter of 50 mm is prepared as a substrate for growth 31 and the NGO substrate 31, Ga raw material, and Al raw material are provided in an HVPE device. Then, temperature of the Ga raw material part and Al raw material part are increased to 850° C. and 800° C., respectively.

Here, flow rate of N₂ carrier gas is set to 12 L/min and flow rate in an HCl line to the Ga raw material part, in an HCl line to the Al raw material part, and in an NH₃ line are respectively set to be 1.4 L/min, 1.4 L/min, and 1.64 L/min after attenuation by the N₂ carrier gas.

Next, the growth temperature (temperature of the NGO substrate) is fixed to 600° C., AlCl is supplied through an Al raw material line, GaCl is supplied through a Ga raw material line, and NH₃ is supplied through the NH₃ line. At this time, flow rate is adjusted so that composition x of Al becomes 0.42. Then, a low temperature protective layer 32 including Al_{0.42}Ga_{0.58}N is grown on the NGO substrate 31 to approximately 100 nm. Subsequently, supply of the raw material gas is stopped and growth temperature is increased to 980° C.

Next, AlCl is supplied from the Al raw material line again, GaCl is supplied from the Ga raw material line, and NH₃ is supplied from the NH₃ line. At this time, flow rate is adjusted so that the composition x of Al becomes 0.42, 0.3, 0.2, and 0.1. Then, the composition gradient layers 33 having AlₓGa₁₋ₓN (x=0.42, 0.3, 0.2, and 0.1) are grown to respectively have a thickness of approximately 100 μm on the AlN low temperature protective layer 32.

Next, supply of the raw material gas through the Al raw material line is stopped, GaCl is supplied through the Ga raw material line, and NH₃ is supplied through the NH3 line. Then, a GaN thick film 34 is grown to 1600 μm on the AlₓGa₁₋ₓN composition gradient layer 33. Subsequently, the temperature is cooled down to the room temperature. In this cooling process, the tensile stress that GaN thick film 34 receives from the NGO substrate 31 becomes larger compared to the embodiment in which the cancel effect is recognized.

A surface of the GaN thick film thus obtained is analyzed by an X-ray diffractometer to observe a diffraction pattern corresponding to a (0002) surface and a (0004) surface of GaN. Moreover, after the GaN thick film 34 is polished for measurement of cathodoluminescence, threading dislocation of approximately between 10³ and 10⁵/cm² is observed. Further, when off angle distribution is measured similarly to the embodiment, off angle distribution is approximately ±0.5°.

Thus, when the GaN epitaxial substrate 3 obtained by the comparison example 2 is compared to the GaN epitaxial substrate 1 obtained by the embodiment, the GaN thickness film 34 has larger warping while having similar crystallinity to that of the embodiment.

Thus, the invention by the inventors has been explained in detail on the basis of the embodiment. However, the present invention is not limited to the above-mentioned embodiment and can be modified within the scope and spirit of the invention.

In the embodiment, a case has been explained, where GaN, which is a GaN based semiconductor, is grown on the NGO substrate. However, the present invention can be applied to a case where a GaN based semiconductor including AlₓGa₁₋ₓN (0<x≦1) is grown on the NGO substrate.

Moreover, the explanation has been given of a case where the GaN based semiconductor epitaxial substrate having a laminated structure of the NGO substrate 11\AlN low temperature protective layer 12\AlₓGa₁₋ₓN layer (the first GaN based semiconductor layer+composition gradient layer) 13\GaN layer (the second GaN based semi-conductor layer) 14 in the embodiment. However, the composition gradient layer may be omitted and a laminated structure of the NGO substrate 11\AlN low temperature protective layer 12\AlₓGa₁₋ₓN layer (the first GaN based semiconductor layer) 13\GaN layer (the second GaN based semi-conductor layer) 14 may be used.

Further, the explanation has been given of a case where the HVPE method is used in the embodiment. However, the present invention can be applied to a case where the metal organic chemical vapor deposition method (MOCVD) or the molecular beam epitaxy (MBE) method is used to epitaxially grow a GaN based semiconductor.

The entire disclosure of Japanese Patent Application No. 2010-081045 filed on Mar. 31, 2010 including description, claims, drawings, and abstract are incorporated herein by reference in its entirety.

Although various exemplary embodiments have been shown and described, the invention is not limited to the embodiments shown. Therefore, the scope of the invention is intended to be limited solely by the scope of the claims that follow.

What is claimed is:

1. A manufacturing method of a GaN based semiconductor epitaxial substrate comprising:
a first step of growing a low-temperature protective layer having AlN on a rare earth perovskite substrate;
a second step of growing a first GaN based semiconductor layer having Alₓ₁Ga₁₋ₓ₁N, in which composition x1 of Al is 0.40≦x1≦0.45, on the low-temperature protective layer; and
a third step of growing a second GaN based semiconductor layer having Alₓ₂Ga₁₋ₓ₂N, in which composition x2 of Al is 0≦x2≦0.45, on the first GaN based semiconductor layer.

2. The manufacturing method of the GaN based semiconductor epitaxial substrate according to claim 1 further comprising a fourth step of growing a composition gradient layer having Alₓ₃Ga₁₋ₓ₃N, in which the composition x3 of Al gradually becomes smaller from the composition x1, on the first GaN based semiconductor layer, wherein
the second GaN based semiconductor layer is grown on the composition gradient layer in the third step.

3. The manufacturing method of the GaN based semiconductor epitaxial substrate according to either claim 1 or 2, wherein the first and the second GaN based semiconductor layers are epitaxially grown on the rare earth perovskite substrate by use of HVPE method supplying chloride gas of one or a plurality of III group elements including Ga and NH₃ and to cause them react.
